(19) United States
(12) Patent Application Publication
(10) Pub. No.: US 2024/0057326 A1
(43) Pub. Date: Feb. 15, 2024

(54) SEMICONDUCTOR DEVICE AND FABRICATION METHOD THEREFOR

(71) Applicant: Yangtze Memory Technologies Co., Ltd., Wuhan (CN)

(72) Inventors: Zhen GUO, Wuhan (CN); Wei XU, Wuhan (CN); Bin YUAN, Wuhan (CN); Li JIANG, Wuhan (CN); ZongLiang HUO, Wuhan (CN)

(73) Assignee: Yangtze Memory Technologies Co., Ltd., Wuhan (CN)

(21) Appl. No.: 17/887,071

(22) Filed: Aug. 12, 2022

(51) Int. Cl. H01L 27/11556; H01L 27/11524; H01L 27/1157; H01L 27/11582

(52) U.S. Cl. CPC H01L 27/11556; H01L 27/11524; H01L 27/1157; H01L 27/11582

(57) ABSTRACT

Aspects of the disclosure provide a semiconductor device. The semiconductor device includes a memory stack of gate layers and insulating layers. The gate layers and the insulating layers are stacked alternatingly and are formed into stair steps in a staircase region. Further, the semiconductor device includes a landing stack formed on the stair steps in the staircase region. The landing stack includes an upper layer that is etch selective to a contact isolation layer that covers the staircase region. Then, the semiconductor device includes a first contact structure on a first stair step of the stair steps. The first contact structure extends through a first contact hole in the contact isolation layer and the landing stack. The first contact structure is connected with a first gate layer (e.g., a top gate layer) of the first stair step.

### TECHNICAL FIELD

The present application describes embodiments generally related to a memory system, semiconductor devices and fabrication processes for the semiconductor devices.

### BACKGROUND

Semiconductor manufactures developed vertical device technologies, such as three dimensional (3D) NAND flash memory technology, and the like to achieve higher data storage density without requiring smaller memory cells. In some examples, a 3D NAND memory device includes a core region and a staircase region. The core region includes a stack of alternating gate layers and insulating layers. The stack of alternating gate layers and insulating layers is used to form memory cells that are stacked vertically. The staircase region includes the respective gate layers in the stair-step form to facilitate forming contacts to the respective gate layers. The contacts are used to connect driving circuitry to the respective gate layers for controlling the stacked memory cells.

### SUMMARY

Aspects of the disclosure provide a semiconductor device. The semiconductor device includes a memory stack of gate layers and insulating layers. The gate layers and the insulating layers are stacked alternatingly and are formed into stair steps in a staircase region. Further, the semiconductor device includes a landing stack formed on the stair steps in the staircase region. The landing stack includes an upper layer that is etch selective to a contact isolation layer that covers the staircase region. Then, the semiconductor device includes a first contact structure on a first stair step of the stair steps. The first contact structure extends through a first contact hole in the contact isolation layer and the landing stack. The first contact structure is connected with a first gate layer (e.g., a top gate layer) of the first stair step.

In some examples, the landing stack with the upper layer extends over the stair steps. In some embodiments, the upper layer is formed of a conductive material.

According to an aspect of the disclosure, the upper layer is formed of a same material as the gate layers. In an example, the upper layer includes tungsten. In some examples, the semiconductor device includes a spacer isolation structure disposed between the upper layer and the first contact structure. The spacer isolation structure isolates the upper layer from the first contact structure. According to an aspect of the disclosure, the spacer isolation structure is disposed in a recessed space of the upper layer from a sidewall of the first contact hole.

In some examples, the landing stack further includes an isolation layer. The isolation layer includes a first portion disposed on a riser sidewall from the first stair step to a second stair step. The first portion of the isolation layer isolates the upper layer from a second gate layer of the second stair step. In some examples, the isolation layer includes a second portion disposed on a sidewall of multiple gate layers and insulating layers. The isolation layer can extend over the stair steps.

Aspects of the disclosure also provide a method for fabricating a semiconductor device. The method includes forming stair steps in a memory stack of gate layers and insulating layers in a staircase region. The gate layers and the insulating layers are stacked alternatingly. Further, the method includes forming a landing stack over the stair steps in the staircase region. The landing stack includes an etch stop layer that is etch selective to a contact isolation layer that covers the staircase region. Then, the method includes forming a first contact structure on a first stair step of the stair steps. The first contact structure extends through a first contact hole in the contact isolation layer and the landing stack. The first contact structure is connected with a first gate layer (e.g., a top gate layer) of the first stair step.

To form the stair steps, in some examples, the method includes forming the stair steps in an initial memory stack for the memory stack. The initial memory stack includes sacrificial layers corresponding to the gate layers. Then, the method includes replacing the sacrificial layers with the gate layers to form the memory stack.

To form the landing stack, in some examples, the method includes depositing an isolation layer that conforms to the stair steps in the initial memory stack, depositing a topside sacrificial layer over the isolation layer, and replacing the topside sacrificial layer with the etch stop layer at a same time as the replacing the sacrificial layers with the gate layers.

To deposit the isolation layer, in some examples, the method includes depositing a silicon dioxide film using atomic layer deposition (ALD) that covers riser sidewalls of the stair steps and sidewalls of multiple gate layers and insulating layers in the staircase region.

To form the first contact structure, in some examples, the method includes forming a spacer isolation structure between the etch stop layer and the first contact structure. The spacer isolation structure isolates the etch stop layer from the first contact structure. To form the spacer isolation structure, the method includes forming a first portion of the first contact hole in the contact isolation layer by etching the contact isolation layer with a stop in the etch stop layer, recessing the etch stop layer that forms a recessed space into the etch stop layer on a sidewall of a second portion of the first contact hole. The second portion of the first contact hole is in the etch stop layer. Then, the method includes forming the spacer isolation structure that fills the recessed space. In an example, the method includes depositing silicon dioxide using atomic layer deposition (ALD). The silicon dioxide fills the recessed space.

To form the first contact structure, the method includes forming a third portion of the first contact hole based on the first portion and the second portion of the first contact hole, and the third portion of the first contact hole exposes the first gate layer of the first stair step. Then, the method includes forming the first contact structure in the first contact hole.

Aspects of the disclosure also provide a memory system device. The memory system device includes a controller coupled to the semiconductor device to control data storage operations on the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B show a perspective view and a cross-sectional view of a semiconductor device according to some embodiments of the disclosure.

FIG. 2 shows a flow chart outlining a process example for fabricating a semiconductor device according to some embodiments of the disclosure.

FIGS. 3A-3I show cross-sectional views of a semiconductor device at various intermediate steps of manufacturing in accordance with some embodiments of the disclosure.

FIG. 4 shows a block diagram of a memory system device according to some examples of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A three dimensional (3D) NAND flash memory device includes vertical memory cell strings formed in a memory stack of gate layers and insulating layers. The gate layers and the insulating layers are stacked alternatingly. The gate layers can correspond to gate terminals of transistors in the vertical memory cell strings. The 3D NAND flash memory device can include a staircase region to facilitate connections to the gate layers. The staircase region includes stair steps, each stair step includes a top gate layer that is one of the gate layers and each gate layer can be a top gate layer of a stair step. In some examples, contact holes are etched through a contact isolation layer to expose respective top gate layers on respective stair steps in the staircase region. Then, contact structures can be formed in the contact holes to connect respective top gate layers of the stair steps to, for example word lines of the 3D NANAD flash memory device.

According to some aspects of the disclosure, to prevent the etch process for forming the contact holes from etching through (also referred to as punch through) a top gate layer of a stair step (the punch through can cause short circuits to another gate layer under the top gate layer), thickness of the top gate layer in the stair step can be increased. The thickness increase of the top gate layers in the staircase region can be performed by a use of a topside sacrificial layer technique in a gate last technology.

In the gate last technology, an initial memory stack of sacrificial layers and insulating layers are formed, and the sacrificial layers and the insulating layers are stacked alternatingly in the initial memory stack. After channel structures are formed in the initial memory stack in an array region and stair steps are formed based on the initial memory stack in the staircase region, the sacrificial layers can be replaced with gate layers to form the memory stack. In some examples, the sacrificial layers are made of silicon nitride, and the insulating layers are made of silicon dioxide.

In some examples, to use the topside sacrificial layer technique, after the formation of the stair steps in the initial memory stack in the staircase region, top sacrificial layers (corresponding to the top gate layers) can be exposed on respective stair steps. Then, a topside sacrificial layer (e.g., an additional silicon nitride layer) can be formed over the stair steps. The topside sacrificial layer can increase the thickness of the top sacrificial layers on the stair steps. The topside sacrificial layer can be patterned to form initial landing pads respectively on the stair steps, and the initial landing pads are isolated from each other. In the process that replaces the sacrificial layers with the gate layers, the initial landing pads can be replaced by material(s) that forms the gate layers to form real landing pads on the stair steps.

In some related examples, the patterning of the topside sacrificial layer relies on a sidewall profile in the staircase region to ensure isolation of the landing pads. In a related example, a thicker top sacrificial layer can cause a gentle slope over a stair riser portion compared to a thinner top sacrificial layer that can cause a steep slope over a stair riser portion. The gentle slope may cause residues of the topside sacrificial layer between adjacent stair steps during the patterning process, the residues may be in touch with the sacrificial layers in the memory stack. During the replacement process to replace the sacrificial layers with the gate layers, the residues can be replaced by the material of the gate layers, and thus can cause leakage or even shorts between word lines. In another related example, a staircase region may include a sidewall of multiple gate layers and insulating layers (also referred to as a great wall in some examples) in the memory stack. When the profile of the sidewall is not steep enough, for example, a portion of the sidewall having a sub shoulder, the patterning process may leave residues at the sub shoulder. When the residues are replaced by the material of the gate layers, the residues can cause leakage or even shorts between word lines.

Some aspects of the disclosure provide techniques to avoid leakage or shorts between word lines. For example, a landing stack can be formed over the stair steps in the staircase region. The landing stack includes an etch stop layer. The landing stack with the etch stop layer can extend over the stair steps. The etch stop layer is etch-selective to a contact isolation layer that covers the staircase region, and can be used as a stop layer for etching contact holes in the contact isolation layer. Thus, when forming contact holes in the contact isolation layer for contact structures, the etch stop layer can prevent the eth process to punch through the top gate layers respectively on the stair steps. Further, the landing stack also includes an isolation layer that extends over the stair steps and can cover the gate layers from the sidewalls of the stair steps, and/or top surfaces of the stair steps, and can isolate the gate layers of the stair steps from the etch stop layer.

In some examples, the etch stop layer is formed of a conductive material, such as including tungsten. Then, a suitable spacer isolation structure can be formed to isolate the contact structures from the etch stop layer.

The techniques provided in the disclosure can reduce profile requirements of sidewalls in the staircase region, and improve process window for forming stair steps in the staircase region. Further, the techniques provided in the disclosure allow thicker topside sacrificial layer (corresponding to the etch stop layer) and can improve the process window for contact hole etching process.

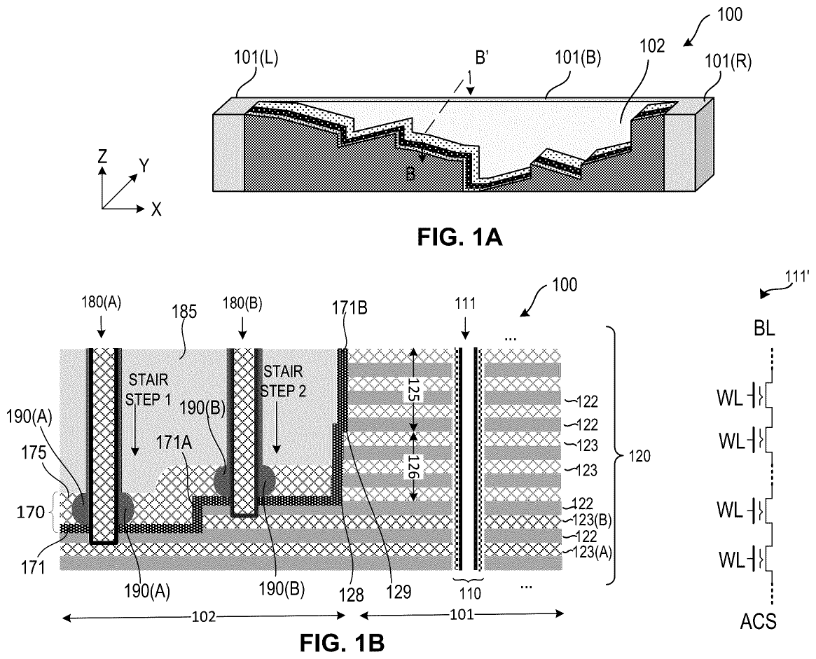

FIG. 1A shows a perspective view of a semiconductor device 100, and FIG. 1B shows a cross sectional view of the semiconductor device 100 along a B-B′ line shown in FIG. 1A according to some embodiments of the disclosure. The semiconductor device 100 includes a memory stack 120 formed in an array region 101 (e.g., 101(L), 101(B) and 101(R)) and a staircase region 102. In the array region, the semiconductor device 100 includes vertical memory cell strings 111 formed in the memory stack 120; and in the staircase region 102, the semiconductor device 100 includes contact structures 180 (e.g., 180(A), 180(B)) that can provide word line driving signals to gate terminals of transistors in the vertical memory cell strings 111. Further, the semiconductor device 100 includes a landing stack 170 that extends over the stair steps in the staircase region 102. The landing stack 170 can be used to improve process windows for forming the contact structures and can be used to avoid leakage between word lines.

It is noted that the semiconductor device 100 can be any suitable device, for example, memory circuits, a semiconductor die with memory circuits formed on the semiconductor die, a semiconductor wafer with multiple semiconductor dies formed on the semiconductor wafer, a semiconductor chip with a stack of semiconductor dies bonded together, a semiconductor package that includes one or more semiconductor dies or chips assembled on a package substrate, and the like.

It is also noted that, the semiconductor device 100 can include other suitable circuitry (not shown), such as logic circuitry, power circuitry, and the like that is formed on the same substrate, or other suitable substrate, and is suitably coupled with the memory cell arrays.

Generally, the semiconductor device 100 is fabricated based on a substrate, such as a silicon (Si) substrate, a germanium (Ge) substrate, a silicon-germanium (SiGe) substrate, and/or a silicon-on-insulator (SOI) substrate. In some examples, the substrate can be in the final product of the semiconductor device 100. In some other examples, the substrate can be removed during fabrication processing and thus the substrate is not in the final product of the semiconductor device 100. For simplicity, the main surface of the substrate is referred to as an X-Y plane, and the direction perpendicular to the main surface is referred to as Z direction.

In the array region 101, vertical memory cell strings 111 are formed based on channel structures 110 in the memory stack 120. In the FIG. 1B example, a vertical memory cell string 111 is shown as representation of an array of vertical memory cell strings 111 formed in the array region 101. FIG. 1B also shows a schematic symbol version of a vertical memory cell string 111′ corresponding to the vertical memory cell string 111. The vertical memory cell strings 111 are formed in the memory stack 120 of layers. The memory stack 120 includes gate layers 123 (e.g., 123, 123(A), 123(B)) and insulating layers 122 that are stacked alternatingly. The gate layers 123 are made of gate stack materials, such as high dielectric constant (high-k) gate insulator layers, metal gate (MG) electrode, and the like. The insulating layers 122 are made of insulating material(s), such as silicon nitride, silicon dioxide, and the like. In some examples, the metal gate electrode for the gate layers 123 can include tungsten, and the insulating layers 122 are formed of silicon dioxide.

It is noted that FIG. 1B shows a portion of the memory stack 120, the memory stack 120 can include additional gate layers and insulating layers above the portion shown in FIG. 1B, and can include additional gate layers and insulating layers below the portion shown in FIG. 1B.

In the array region 101, the channel structures 110 are formed in the memory stack 120. The memory stack 120 and the channel structures 110 are configured to form transistors that are stacked vertically. In some examples, a stack of transistors includes memory cells and select transistors, such as one or more bottom select transistors, one or more top select transistors and the like. In some examples, the stack of transistors can include one or more dummy select transistors. The gate terminals of the transistors in the vertical memory cell string 111 are connected to word line (WL) driving circuits, and the gate layers 123 can correspond to word lines. In some examples, one end of the stack of transistors is connected to a bit line (BL), and another end of the stack of transistors is connected to an array common source (ACS).

As shown in the FIG. 1A, the staircase region 102 can be disposed at a center of the array region 101. For example, the array region 101 includes a left portion 101(L), a right portion 101(R) and bridge portion(s) 101(B). The left portion 101(L) and the right portion 101(R) are interconnected by the bridge portion(s) 101(B). In some examples, the staircase region 102 is surrounded by the left portion 101(L), the right portion 101(R), and the bridge portion(s) 101(B). It is noted that the present disclosure is not limited to the placement of the staircase region(s) and array region(s).

In the staircase region 102, stair steps are formed in the memory stack 120, each stair step includes a top gate layer associated with the stair step. For example, the gate layer 123(A) is the top gate layer of the stair step 1, and the gate layer 123(B) is the top gate layer of the stair step 2. The contact structures 180 (e.g., 180(A), 180(B)) are formed on the stair steps in the staircase region 102. For example, in the staircase region 102, the contact structures 180 are formed based on contact holes in a contact isolation layer 185. The contact structures 180 can connect the respective top gate layers of the stair steps with routing wires (not shown) that are connected to word line driving circuitry. For example, the contact structure 180(A) is conductively connected with the gate layer 123(A), and the contact structure 180(B) is conductively connected with the gate layer 123(B). The contact structures 180 are formed of suitable conductive materials, such as titanium (Ti), titanium nitride (TiN), tungsten and the like.

According to an aspect of the disclosure, the semiconductor device 100 includes a landing stack 170 that is formed in the staircase region 102. The landing stack 170 extends over the stair steps, for example cover the top surfaces of the stair steps and sidewalls of the stair steps. The landing stack 170 includes an upper structure such as an etch stop layer 175 that can be used as an etch stop for a contact hole etch process that forms contact holes in the contact isolation layer 185. The etch stop layer 175 can be used to protect the top gate layers from being punched through during the contact hole etch process. For example, the etch stop layer 175 is configured to be etch selective to the contact isolation layer 185. In an example, an etch rate ratio of the contact isolation layer 185 to the etch stop layer 175 in the contact hole etch process is over 10, such as 20, and the like. In some examples, the contact isolation layer 185 is formed of silicon oxide, and the etch stop layer 175 can be formed of the same material(s) as the gate layers. For example, the etch stop layer 175 includes high dielectric constant (high-k) gate insulator and tungsten.

In the FIG. 1B example, the landing stack 170 also includes an isolation layer 171 that isolates the etch stop layer 175 from the gate layers 123. In some examples, the isolation layer 171 is deposited over the stair steps, and covers the top surfaces of the stair steps and the sidewalls of the stair steps. Then, the etch stop layer 175 can be formed over the isolation layer 171, thus the isolation layer 171 isolates the etch stop layer 175 from the gate layers 123. For example, a portion 171A of the isolation layer 171 covers a riser sidewall between the stair step 1 and the stair step 2, and can isolate the gate layer 123(B) from the etch stop layer 175.

In the FIG. 1B example, on a top surface of a stair step, the isolation layer 171 and one of the insulating layers 122 are between the top gate layer and the etch stop layer 175, and can isolate the etch stop layer 175 from the top gate layer. For example, on the stair step 1, the isolation layer 171 and one of the insulating layers 122 are between the top gate layer 123(A) and the etch stop layer 175, and can isolate the etch stop layer 175 from the top gate layer 123(A); and on the stair step 2, the isolation layer 171 and one of the insulating layers 122 are between the top gate layer 123(B) and the etch stop layer 175, and can isolate the etch stop layer 175 from the top gate layer 123(B).

In some other examples (not shown), on the top surface of a stair step, the isolation layer 171 is directly on the top gate layer to isolate etch stop layer 175 from the top gate layer.

According to some aspects of the disclosure, the staircase region 102 may include walls of multiple gate layers 123 and insulating layers 122. A wall of multiple gate layers 123 and insulating layers 122 can be referred to as a great wall. For example, FIG. 1B shows a great wall 128 of multiple gate layers 123 and insulating layers 122 at the boundary of the array region 101 and the staircase region 102. In some examples, the great wall 128 is a result of a chop process and other processing techniques to form stair steps in the staircase region 102. The chop process is used to remove (e.g., etch) multiple gate layers 123 and insulating layers 122 in selected regions. In some examples, a great wall can be a result of multiple rounds of the chop process. For example, the great wall 128 at the boundary of the array region 101 and the staircase region 102 is a result of a first round of the chop process that removes a first portion 125 of gate layers 123 and insulating layers 122 in the staircase region 102 and a second round of the chop process that removes a second portion 126 of gate layers 123 and insulating layers 122 in the staircase region 102. Due to process variations (e.g., alignment variation, etch variation, and the like), the great wall 128 has a portion 129 of a shoulder shape at an interface of the first portion 125 and the second portion 126, and the portion 129 is referred to as a sub-shoulder 129. According to an aspect of the disclosure, the isolation layer 171 also extends and covers the sidewalls of the great walls, such as the sidewall of the great wall 128. As show in FIG. 1B, a portion 171B of the isolation layer 171 is laid on the sidewall of the great wall 128 and can protect the sidewall of the great wall 128.

In some embodiments, the isolation layer 171 is made of silicon dioxide. In some examples, the isolation layer 171 is formed by on atomic layer deposition (ALD), and has a relatively good step coverage.

Further, according to an aspect of the disclosure, the semiconductor device 100 includes spacer isolation structures 190 (e.g., 190(A), 190(B)) that isolate the contact structures 180 from the etch stop layer 175. The spacer isolation structures 190 can include any suitable insulating material(s), such as silicon oxide, silicon dioxide, and the like. In some examples, the spacer isolation structures 190 is formed by filling the insulating material in a recessed space of the etch stop layer 175. In some examples, the spacer isolation structure 190(A) is formed in a recessed space of the etch stop layer 175 from a sidewall of the contact hole for the contact structure 180(A), and can isolate the etch stop layer 175 from the contact structure 180(A). Similarly, the spacer isolation structure 190(B) is formed in a recessed space of the etch stop layer 175 from a sidewall of the contact hole for the contact structure 180(B), and can isolate the etch stop layer 175 from the contact structure 180(B).

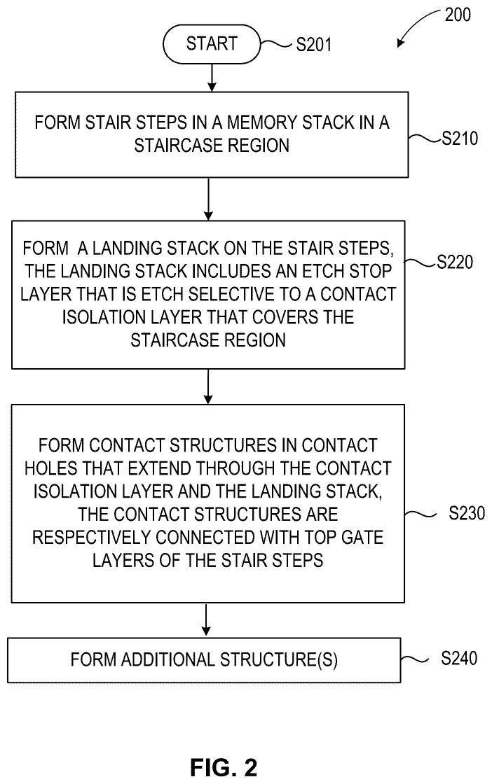

FIG. 2 shows a flow chart outlining a process 200 for fabricating a semiconductor device, such as the semiconductor device 100, according to some embodiments of the disclosure.

At S210, stair steps are formed in a memory stack in a staircase region. The memory stack includes gate layers and insulating layers stacked alternatingly. In some examples, the stair steps are formed in an initial memory stack for the memory stack. The initial memory stack includes sacrificial layers and the insulating layers stacked alternatingly. After channel structures are formed in an array region of the initial memory stack, and the stair steps are formed in a staircase region of the initial memory stack, the sacrificial layers can be replaced by the gate layers to form the memory stack.

At S220, a landing stack is formed over the stair steps. The landing stack includes an etch stop layer that is etch selective to a contact isolation layer in the staircase region. In some examples, an isolation layer is deposited over the stair steps in the initial memory stack, and a topside sacrificial layer is deposited over the isolation layer. The topside sacrificial layer can be replaced with the etch stop layer at the same time as the replacement of the sacrificial layers with the gate layers. In some examples, the isolation layer is made of silicon dioxide film that is deposited using atomic layer deposition (ALD). The silicon dioxide film by ALD has good step coverage, and can covers riser sidewalls of the stair steps and sidewalls of great walls of multiple gate layers and insulating layers in the staircase region.

At S230, contact structures to the gate layers are formed on the stair steps in the staircase region. The contact structures are formed in contact holes that extend the contact isolation layer and the landing stack. The contact structures are respectively connected with the top gate layers of the stair steps. For example, the contact structure 180(A) is formed in a contact hole that extends in the contact isolation layer 185 and the landing stack 170, is connected with the gate layer 123(A) of the stair step 1.

In an example, a first portion of the contact hole is formed in the contact isolation layer 185 by etching the contact isolation layer 185 with a stop in the etch stop layer 175. Then, the etch stop layer 175 is recessed to expose the isolation layer 171 and the form the recessed space into the etch stop layer 195. Then, spacer isolation structures can be formed from the sidewall of the contact hole. For example, a spacer isolation layer can be deposited, and the spacer isolation layer fills the recessed space and forms the spacer isolation structures 190. In some examples, the spacer isolation layer is formed by depositing silicon dioxide using atomic layer deposition (ALD).

Further, a second portion of the contact hole is formed based on the first portion of the contact hole. For example, an oxide etch process can be performed to form the second portion of the contact hole in the isolation layer and an insulating layer above the top gate layer. The second portion of the contact hole exposes the top gate layer of the stair step, such as the gate layer 123(A) of the stair step 1. Then, materials for the contact structure 180(A), such as titanium (Ti), titanium nitride (TiN), tungsten and the like can be deposited in the contact hole, and can be connected with the gate layer 123(A).

At S240, additional structure, such as routing wires, passivation, bonding structures, and the like can be formed.

It is noted that the process 200 can be suitably adapted. Step(s) in the process 200 can be modified and/or omitted. Additional step(s) can be added. Any suitable order of implementation can be used.

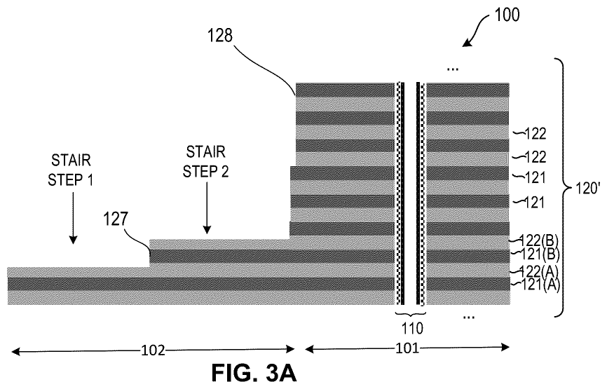

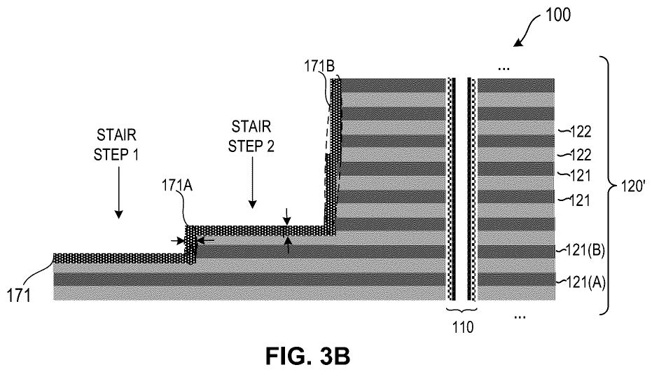

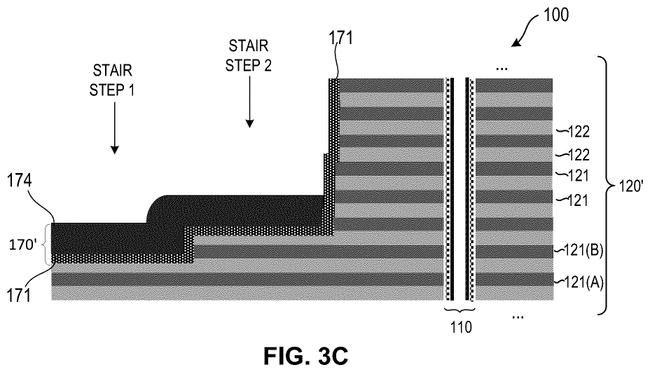

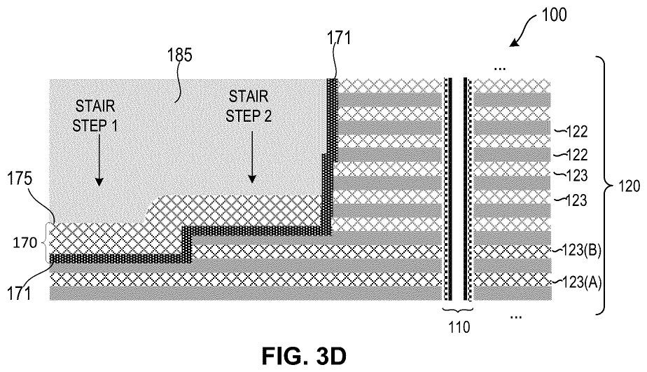

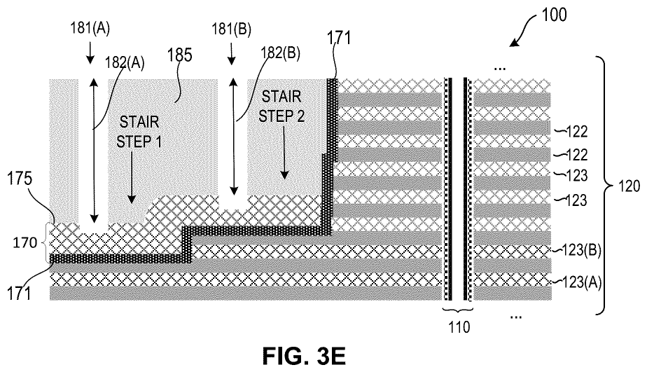

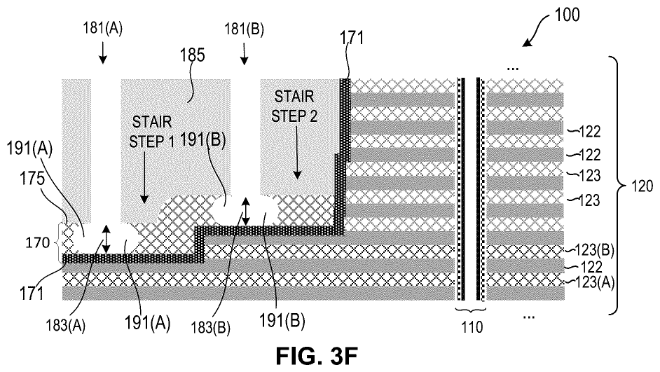

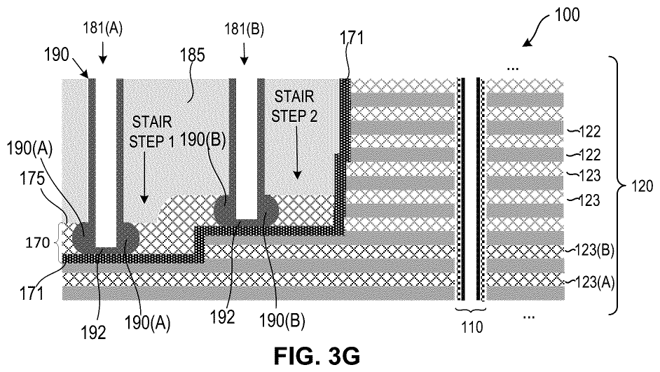

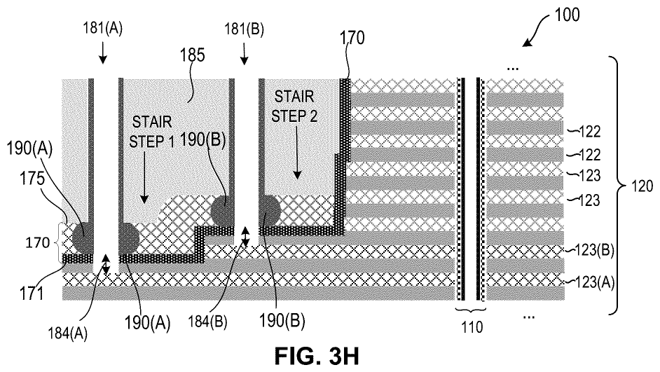

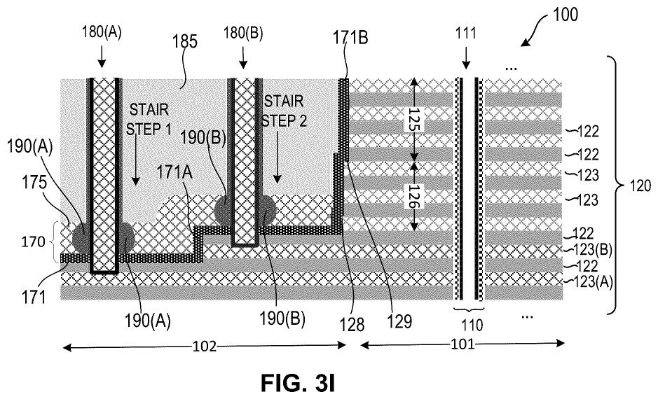

FIGS. 3A-3I show cross-sectional views of a semiconductor device, such as the semiconductor device 100, at various intermediate steps of wafer level manufacturing, in accordance with some embodiments of the present disclosure.

FIG. 3A shows a cross-sectional view of the semiconductor device 100 after stair steps are formed in the staircase region 102. In an example, an initial memory stack 120′ of layers is deposited on a substrate (not shown). In the FIG. 3A example, the initial memory stack 120′ includes sacrificial layers 121 (e.g., 121, 121(A), 121(B)) and insulating layers 122 that are stacked alternatingly. In an example, the sacrificial layers 121 are made of silicon nitride, and the insulating layers 122 are made of silicon dioxide. Further, channel structures 110 are formed in the initial memory stack 120′ in an array region 101, and stair steps, such as stair step 1 and stair step 2 in FIG. 3A, are formed in the initial memory stack 120′ in a staircase region 102. In some example, the process (e.g., etch process) to form a stair step can stop expose an insulating layer 122 on a top sacrificial layer 121 associated with the stair step. For example, the process (e.g., etch process) to form the stair step 1 stops and exposes on an insulating layer 122(A) above the sacrificial layer 121(A); the process (e.g., etch process) to form the stair step 2 stops and exposes an insulating layer 122(B) above the sacrificial layer 121(B).

Due to the formation of the stair steps, the staircase region 102 includes sidewalls of sacrificial layer(s) and insulating layer(s). For example, the staircase region 102 includes a riser sidewall 127 that is transitional portion from the stair step 1 to the stair step 2. The staircase region 102 also includes a great wall 128 that is between the staircase region 102 and the array region 101.

FIG. 3B shows a cross-sectional view of the semiconductor device 100 after an isolation layer 171 is deposited. In an example, the isolation layer 171 has a relatively good step coverage. For example, the isolation layer 171 conforms to the stair steps in the initial memory stack 120′. In an example, the isolation layer 171 is a silicon dioxide film deposited using atomic layer deposition (ALD). Thus, a portion of the isolation layer 171 is deposited on the sidewalls, such as a portion 171A on riser sidewalls of the stair steps, a portion 171B on sidewall of a great wall of multiple sacrificial layers 121 and insulating layers 122. In some examples, a width (W) of the isolation layer 171 on the sidewalls is about the same as a thickness (T) of the isolation layer 171 within process variation. In an example, the isolation layer 171 is in a range of 1 nm to 500 nm.

FIG. 3C shows a cross-sectional view of the semiconductor device 100 after an initial landing stack 170′ is formed. In some examples, a topside sacrificial layer 174 is deposited. In some examples, the topside sacrificial layer 174 can be patterned to leave the topside sacrificial layer 174 in the staircase region 102. In an example, a portion of the topside sacrificial layer 174 on the sidewall of the great wall 128 is removed. For example, a suitable mask layer (e.g., soft mask layer and/or hard mask layer) can be formed to cover the topside sacrificial layer 174 in the staircase region 102. The topside sacrificial layer 174 in the array region 101 and in the region of the sidewall of the great wall 128 can be exposed. Then, a wet etch process can be used to remove the exposed portion of the topside sacrificial layer 174.

FIG. 3D shows a cross-sectional view of the semiconductor device 100 after a replacement of the sacrificial layers with gate layers. For example, the sacrificial layers 121 are replaced with gate layers 123, thus the real memory stack 120 that includes the gate layers 123 and the insulating layers 122 is formed. Further, at the same time, the topside sacrificial layer 174 is replaced by gate material(s) to form the etch stop layer 175, thus the landing stack 170 that includes the etch stop layer 175 and the isolation layer 171 is formed.

In some examples, a contact isolation layer 185 is formed in the staircase region 102 before the replacement of the sacrificial layers. In an example, the contact isolation layer 185 is formed of silicon oxide, and can be deposited using high density plasma (HDP) deposition. The contact isolation layer 185 can be suitably planarized, for example, using chemical mechanical polishing (CMP) process. Then, the sacrificial layers, including the sacrificial layers 121 and the topside sacrificial layer 174 can be replaced by material(s) for gate layers. In some examples, trenches (not shown) can be formed in the initial memory stack 120′. Based on the trenches, the sacrificial layers 121 and the topside sacrificial layer 174 can be removed (e.g., using suitable wet etch process) to leave space for material(s) of gate layers. Further, based on the trenches, the material(s) for the gate layers (e.g., high-k isolation, tungsten and the like) can be filled into the space. Then, the trenches can be suitably filled.

It is noted that the replacement of the sacrificial layers with gate layers can also replace the topside sacrificial layer 174 with the etch stop layer 175.

FIGS. 3E-3H show an example of forming contact holes for contact structures. The contact holes can expose the top gate layers. In some examples, each of the contact holes includes three portions, such as a first portion in the contact isolation layer 185, a second portion in the etch stop layer 175, and a third portion in an isolation stack including the isolation layer 171 and an insulating layer above the top gate layer.

FIG. 3E shows a cross-sectional view of the semiconductor device 100 after first portions of contact holes are formed. In some examples, a contact hole etch process to etch the contact isolation layer 185 can be performed based on a contact mask. The contact hole etch process can be configured with a stop based on the material of the etch stop layer 175, such as tungsten. Because of the thickness differences of the contact isolation layer 185 on different stair steps, the contact hole etch process may be configured to over etch in order to make sure that all the contact holes are etched through the contact isolation layer 185. The etch stop layer 175 can increase process window for the contact hole etch process, and can be thick enough to allow the contact hole etch process to stop in the etch stop layer 175 and can avoid etching into the gate layers, such as the gate layer 123(A), the gate layer 123(B).

As shown, a first portion 182(A) of a contact hole 181(A) is formed on the stair step 1, and the first portion 182(A) of the contact hole 181(A) may be formed with a stop in the etch stop layer 175. Similarly, a first portion 182(B) of a contact hole 181(B) is formed on the stair step 2, and the first portion 182(B) of the contact hole 181(B) may be formed with a stop in the etch stop layer 175.

FIG. 3F shows a cross-sectional view of the semiconductor device 100 after a recess of the etch stop layer 175. In an example, the etch stop layer 175 includes tungsten, and a tungsten recess process can be performed for example by a wet etch process of the tungsten. In an example, the tungsten recess process can remove the tungsten isotropically. For example, the tungsten recess process removes the tungsten in a vertical direction to form the second portions 183 (e.g., 183(A), 183(B)) of the contact holes 181, and expose the isolation layer 171. Also, the tungsten recess process removes the tungsten in a horizontal direction to form recess spaces 191 (e.g., 191(A), 191(B)) into the etch stop layer 175.

FIG. 3G shows a cross-sectional view of the semiconductor device 100 after a formation of spacer isolation structures 190 (e.g., 190(A), 190(B)). In some examples, a layer of silicon dioxide can be deposited for example using ALD process. The silicon dioxide can be deposited on the sidewalls of the first portions of the contact holes, the sidewalls of the second portions of the contact holes, and the bottom of the second portions 183 of the contact holes 181. For example, the silicon dioxide can be deposited into the recess spaces 191 to form the spacer isolation structures 190. In an example, a thickness of the etch stop layer 175 is in a range of 50 nm to 70 nm, and the silicon dioxide can be deposited with a thickness of 35 nm to 60 nm.

It is noted that excess silicon dioxide maybe deposited on the top surface of the contact isolation layer 185, and the excess silicon dioxide can be removed for example by CMP process. It is also noted that the silicon dioxide can be deposited at the bottom of the second portion 183 of the contact holes 181, such as shown by 192.

FIG. 3H shows a cross-sectional view of the semiconductor device 100 after the contact holes 181 are fully formed. In some examples, an etch process based on physical argon ion bombardment can be performed to remove the silicon dioxide 192 at the bottom of the second portions 183 of the contact holes 181 and further remove the isolation layer 171 and insulating layer 122 exposed by the contact holes 181, and form the third portions 184 (e.g., 184(A), 184(B)) of the contact holes 181. The contact holes 181 finally expose the top gate layers on the stair steps. For example, the contact hole 181(A) exposes the gate layer 123(A), and the contact hole 181(B) exposes the gate layer 123(B).

FIG. 3I shows a cross-sectional view of the semiconductor device 100 after contact structures 180 are formed. In some examples, conductive material(s), such as titanium (Ti), titanium nitride (TiN), tungsten can be used to fill the contact holes 181, and suitably planarization process, such as CMP process can be used to remove excess conductive material(s) and planarize the surface. In the FIG. 3I example, a contact structure 180(A) is formed on the stair step 1, the contact structure 180(A) is conductively connected with the gate layer 123(A). Further, a contact structure 180(B) is formed on the stair step 2, the contact structure 180(B) is conductively connected with the gate layer 123(B).

It is noted that additional process(es), such as backend processes that form routing wires, passivation layer(s), and the like can be performed afterwards.

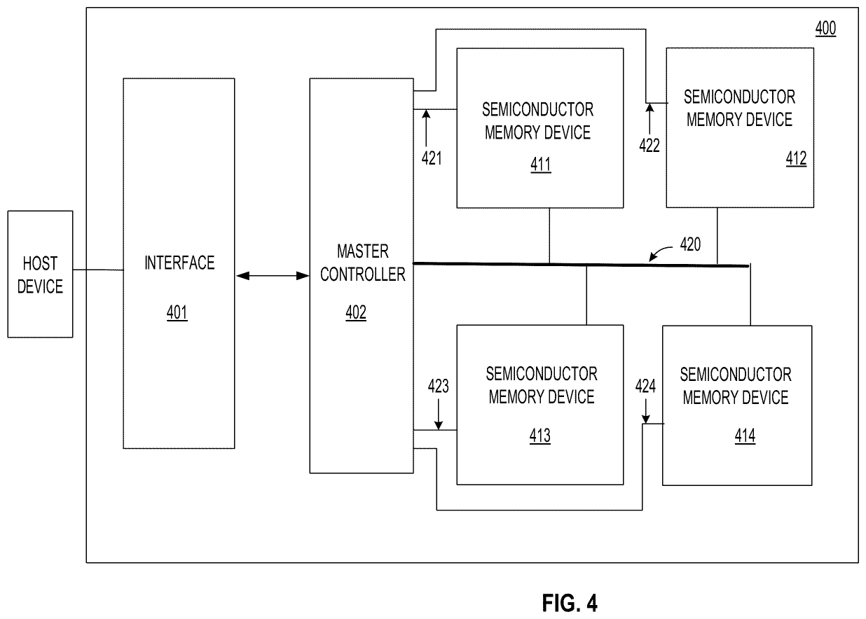

FIG. 4 shows a block diagram of a memory system device 400 according to some examples of the disclosure. The memory system device 400 includes one or more semiconductor memory devices, such as shown by semiconductor memory devices 411-414, that are respectively configured similarly as the semiconductor device 100. In some examples, the memory system device 400 is a solid state drive (SSD).

The memory system device 400 includes other suitable components. For example, the memory system device 400 includes an interface 401 and a master controller 402 coupled together as shown in FIG. 4. The memory system device 400 can include a bus 420 that couples the master controller 402 with the semiconductor memory devices 411-414. In addition, the master controller 402 is connected with the semiconductor memory devices 411-414 respectively, such as shown by respective control lines 421-424.

The interface 401 is suitably configured mechanically and electrically to connect between the memory system device 400 and a host device, and can be used to transfer data between the memory system device 400 and the host device.

The master controller 402 is configured to connect the respective semiconductor memory devices 411-414 to the interface 401 for data transfer. For example, the master controller 402 is configured to provide enable/disable signals respectively to the semiconductor memory devices 411-414 to active one or more semiconductor memory devices 411-414 for data transfer.

The master controller 402 is responsible for the completion of various instructions within the memory system device 400. For example, the master controller 402 can perform bad block management, error checking and correction, garbage collection, and the like.

The foregoing outlines features of several examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the examples introduced herein. Those skilled in the art should also realize that such equivalent constructions do not depart from the spirit and scope of the present disclosure, and that they may make various changes, substitutions, and alterations herein without departing from the spirit and scope of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a memory stack of gate layers and insulating layers, the gate layers and the insulating layers being stacked alternatingly and being formed into stair steps in a staircase region;
a landing stack formed on the stair steps in the staircase region, the landing stack comprising an upper layer that is etch selective to a contact isolation layer that covers the staircase region; and
a first contact structure on a first stair step of the stair steps, the first contact structure extending through a first contact hole in the contact isolation layer and the landing stack and being connected with a first gate layer of the first stair step.

2. The semiconductor device of claim 1, wherein:
the landing stack with the upper layer extends over the stair steps.

3. The semiconductor device of claim 2, wherein the upper layer is formed of a conductive material.

4. The semiconductor device of claim 2, wherein the upper layer is formed of a same material in the gate layers.

5. The semiconductor device of claim 3, further comprising:
a spacer isolation structure disposed between the upper layer and the first contact structure, the spacer isolation structure isolating the upper layer from the first contact structure.

6. The semiconductor device of claim 5, wherein:
the spacer isolation structure is disposed in a recessed space of the upper layer from a sidewall of the first contact hole.

7. The semiconductor device of claim 1, wherein the landing stack further comprises:
an isolation layer that comprises a first portion disposed on a riser sidewall from the first stair step to a second stair step, the first portion isolating the upper layer from a second gate layer of the second stair step.

8. The semiconductor device of claim 7, wherein the isolation layer comprises:
a second portion disposed on a sidewall of multiple gate layers and insulating layers.

9. The semiconductor device of claim 7, wherein the isolation layer extends over the stair steps.

10. The semiconductor device of claim 7, wherein the isolation layer is formed on an insulating layer above the first gate layer.

11. The semiconductor device of claim 1, wherein a material of the upper layer is tungsten.

12. A method for fabricating a semiconductor device, comprising:
forming stair steps in a memory stack of gate layers and insulating layers in a staircase region, the gate layers and the insulating layers being stacked alternatingly;
forming a landing stack over the stair steps in the staircase region, the landing stack comprising an etch stop layer that is etch selective to a contact isolation layer that covers the staircase region; and
forming a first contact structure on a first stair step of the stair steps, the first contact structure extending through a first contact hole in the contact isolation layer and the landing stack, the first contact structure being connected with a first gate layer of the first stair step.

13. The method of claim 12, wherein the forming the stair steps further comprises:
forming the stair steps in an initial memory stack for the memory stack, the initial memory stack comprising sacrificial layers corresponding to the gate layers, the sacrificial layers comprising a first sacrificial layer corresponding to the first gate layer; and
replacing the sacrificial layers with the gate layers to form the memory stack.

14. The method of claim 13, wherein the forming the landing stack further comprises:
depositing an isolation layer over the stair steps in the initial memory stack;
depositing a topside sacrificial layer over the isolation layer; and
replacing the topside sacrificial layer with the etch stop layer at a same time as the replacing the sacrificial layers with the gate layers.

15. The method of claim 14, wherein the depositing the isolation layer further comprises:
depositing a silicon dioxide film using atomic layer deposition (ALD) that covers riser sidewalls of the stair steps and sidewalls of multiple gate layers and insulating layers in the staircase region.

16. The method of claim 14, wherein the forming the first contact structure further comprises:
forming a spacer isolation structure between the etch stop layer and the first contact structure, the spacer isolation structure isolating the etch stop layer from the first contact structure.

17. The method of claim 16, wherein the forming the spacer isolation structure further comprises:
forming a first portion of the first contact hole in the contact isolation layer by etching the contact isolation layer with a stop in the etch stop layer;
recessing the etch stop layer that forms a recessed space into the etch stop layer from a sidewall of a second portion of the first contact hole, the second portion of the first contact hole being in the etch stop layer; and
forming the spacer isolation structure that fills the recessed space.

18. The method of claim 17, wherein the forming the spacer isolation structure further comprises:
depositing silicon dioxide using atomic layer deposition (ALD), the silicon dioxide filling the recessed space.

19. The method of claim 17, wherein the forming the first contact structure further comprises:
forming a third portion of the first contact hole based on the first portion and the second portion of the first contact hole, the third portion of the first contact hole exposing the first gate layer of the first stair step; and
forming the first contact structure in the first contact hole.

20. A memory system device, comprising:
a controller coupled to a semiconductor memory device to control data storage operations on the semiconductor memory device; and
the semiconductor memory device comprising:
a memory stack of gate layers and insulating layers, the gate layers and the insulating layers being stacked alternatingly and being formed into stair steps in a staircase region;
a landing stack formed on the stair steps in the staircase region, the landing stack comprising an etch stop layer that is etch selective to a contact isolation layer that covers the staircase region; and
a first contact structure on a first stair step of the stair steps, the first contact structure extending through a first contact hole in the contact isolation layer and the landing stack and being connected with a first gate layer of the first stair step.
